(19) United States
(12) Patent Application Publication
(10) Pub. No.: US 2025/0377397 A1
(43) Pub. Date: Dec. 11, 2025

(54) POSITION ADJUSTMENT DEVICE, POSITION ADJUSTMENT METHOD, AND STORAGE MEDIUM

(71) Applicant: NEC Platforms, Ltd., Kanagawa (JP)

(72) Inventor: Takahiro SUZUKI, Kanagawa (JP)

(73) Assignee: NEC Platforms, Ltd., Kanagawa (JP)

(21) Appl. No.: 19/215,607

(22) Filed: May 22, 2025

(30) Foreign Application Priority Data
Jun. 5, 2024 (JP) 2024-091-454

(51) Int. Cl. G01R 31/00; G01B 11/00; G01R 1/04

(52) U.S. Cl. CPC G01R 31/002; G01B 11/002; G01R 1/04

(57) ABSTRACT

A position adjustment device acquires positions of multiple target devices, identifies a center position of a virtual circle so that the plurality of target devices are located within the virtual circle, and calculates movement information for aligning the center position with a predetermined position.

This application is based upon and claims the benefit of priority from Japanese patent application No. 2024-091454, filed on Jun. 5, 2024, the disclosure of which is incorporated herein in its entirety by reference.

### TECHNICAL FIELD

The present disclosure relates to a position adjustment device, a position adjustment method, and a storage medium.

### BACKGROUND ART

There may be cases where a target device needs to be moved to a predetermined location. For example, Japanese Unexamined Patent Application Publication No. 2009-058460 (Patent Document 1) discloses the configuration of an unwanted electromagnetic radiation measuring system. Patent Document 1 also discloses that the equipment under test (EUT) is placed on a turntable and adjusted so that the electromagnetic wave radiation source of the EUT is positioned at the center of the rotation axis of the turntable, and that the turntable has a rotation drive mechanism and can be freely rotated around the rotation axis (paragraphs 0065 and 0066 of Patent Document 1).

There has been a demand for a technique that allows easy movement of the above-mentioned target device to a predetermined position.

An example object of the present disclosure is to provide a position adjustment device, a position adjustment method, and a program that solve the above-mentioned problem.

### SUMMARY

A position adjustment device according to one example aspect of the present disclosure includes a position acquisition means for acquiring the positions of a plurality of target devices; a center position identification means for identifying a center position of a virtual circle that includes the plurality of target devices within the circle; and a movement information calculation means for calculating movement information for aligning the center position with a predetermined position.

A position adjustment method according to one example aspect of the present disclosure acquires the positions of a plurality of target devices; identifies a center position of a virtual circle that includes the plurality of target devices within the circle; and calculates movement information for aligning the center position with a predetermined position.

A non-transitory storage medium storing a program according to one example aspect of the present disclosure causes a computer to function as a position acquisition means for acquiring the positions of a plurality of target devices; a center position identification means for identifying a center position of a virtual circle that includes the plurality of target devices within the circle; and a movement information calculation means for calculating movement information for aligning the center position with a predetermined position.

### BRIEF DESCRIPTION OF THE DRAWINGS

FIG. 1 is a first diagram showing an overview of a radiated emission test system according to the present disclosure.

FIG. 2 is a top view of a base on which a target device according to the present disclosure is placed.

FIG. 3 is a diagram showing a state after position adjustment of a target device according to the present disclosure.

FIG. 4 is a second diagram showing an overview of a radiated emission test system according to the present disclosure.

FIG. 5 is a diagram showing the appearance of a position adjustment device according to the present disclosure.

FIG. 6 is a diagram showing the relationship between a target device, a base, and a turntable according to the present disclosure.

FIG. 7 is a diagram showing the relationship between a moving mechanism and a guide rail according to the present disclosure.

FIG. 8 is a diagram showing an example of movement information according to the present disclosure.

FIG. 9 is a hardware configuration diagram of a position adjustment device according to the present disclosure.

FIG. 10 is a functional block diagram of a position adjustment device according to the present disclosure.

FIG. 11 is a diagram showing an overview of the process of the radiated emission test system according to the present disclosure.

FIG. 12 is a diagram showing a processing flow of the position adjustment device according to the present disclosure.

FIG. 13 is a diagram showing another configuration of the position adjustment device according to the present disclosure.

FIG. 14 is a diagram showing another processing flow of the position adjustment device according to the present disclosure.

### EXAMPLE EMBODIMENT

Each example embodiment will be described below with reference to the drawings. In all drawings, the same or corresponding components are given the same reference numerals, and common explanations shall be omitted.

### First Example Embodiment

Hereinbelow, the position adjustment device according to the present disclosure will be described with reference to the drawings.

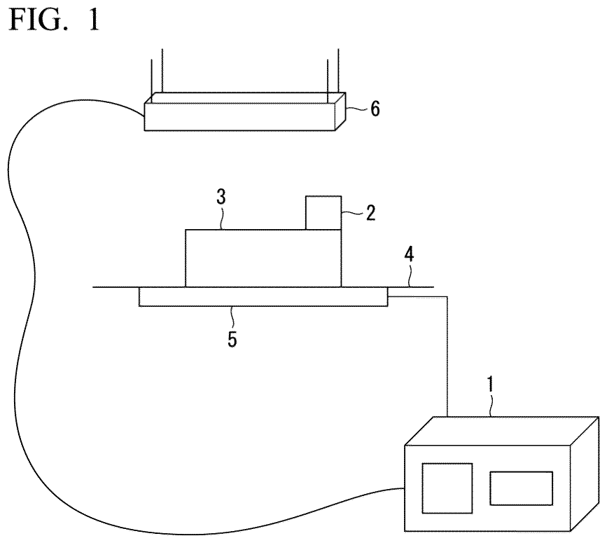

FIG. 1 is a first schematic diagram of a radiated emission test system including a position adjustment device. FIG. 1 shows a radiated emission test system for measuring radiated emissions for Electromagnetic Compatibility (EMC). The radiated emission test system will hereinafter be referred to as system 100. The system 100 includes a position adjustment device 1, a target device 2, a base 3, a turntable 4, a moving mechanism 5, and a scanner 6. The system 100 is installed in an anechoic chamber, and the scanner 6 is installed near the ceiling of the anechoic chamber.

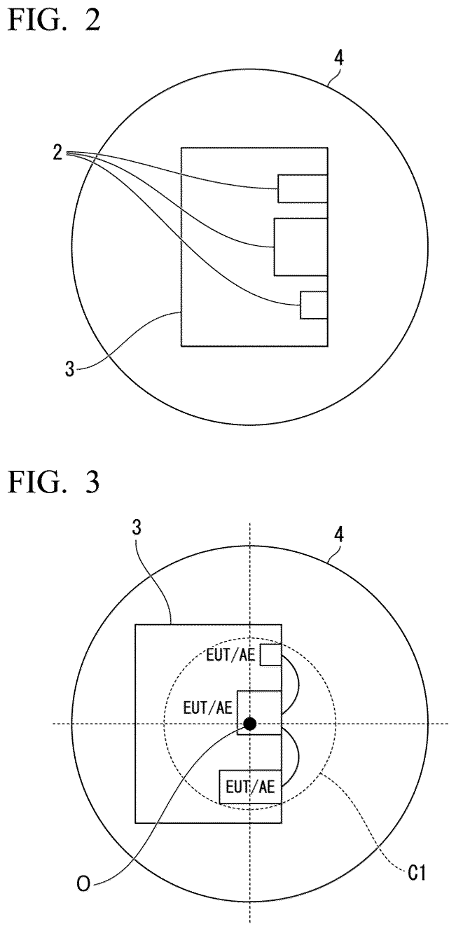

FIG. 2 is a top view of the base on which target devices are placed.

The target device 2 may include a plurality of devices such as equipment under test (EUT) that emits electromagnetic waves and associated equipment (AE) for the test. The target devices 2 of the present disclosure include three target devices 2. As an example, the target device 2 may be a PC main body, a monitor, a peripheral device connected to the PC main body, and the like.

FIG. 3 is a diagram showing the state of the target device after the position adjustment.

The position adjustment device 1 identifies the center position of a virtual outer circumferential circle C1 that includes the target devices 2 inside the circle based on the positions of the target devices 2, and calculates movement information for aligning the center position with a predetermined position. As an example, the center position O of the turntable 4 is set to a predetermined position in advance, and the position adjustment device 1 controls the center position O to coincide with the center position of the virtual outer circumferential circle C1. The target devices 2 are placed on the base 3, and the base 3 may be rotatable by a turntable. The base 3 is equipped with a moving mechanism 5 which will be described below. The scanner 6 scans the base 3 on which the target devices 2 are placed. The scanner 6 may be a camera that takes an image of the base 3 on which the target devices 2 are placed.

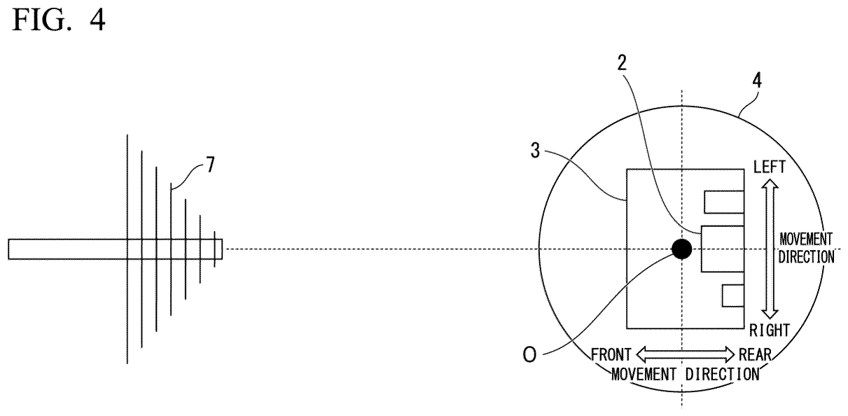

FIG. 4 is a second schematic diagram of a radiated emission test system. As shown in FIG. 4, the system 100 includes an antenna 7. The system 100 receives electromagnetic noise emitted by an electronic device in the target devices 2 via the antenna 7 and measures the intensity of the electromagnetic noise. In a case where performing radiated emission measurements, the system 100 needs to align the center of a virtual outer circumferential circle that includes the three target devices 2, including the electronic devices and auxiliary equipment to be measured, with a predetermined position, such as the center O of the turntable 4. The turntable 4 is predetermined based on the direction and position of the antenna 7. As shown in FIG. 4, the base 3 placed on the turntable 4 can be moved in the front/rear direction about an axis that is the center O of the antenna and the turntable, and in the left/right direction perpendicular to the axis. In the present disclosure, the position adjustment device 1 can be moved in the front/rear direction by using the moving mechanism 5 of the base 3. In the present disclosure, movements in the left and right directions may be performed by a person. In another example embodiment of the system 100, the position adjustment device 1 may be able to freely move the base 3 in the front/rear and left/right directions.

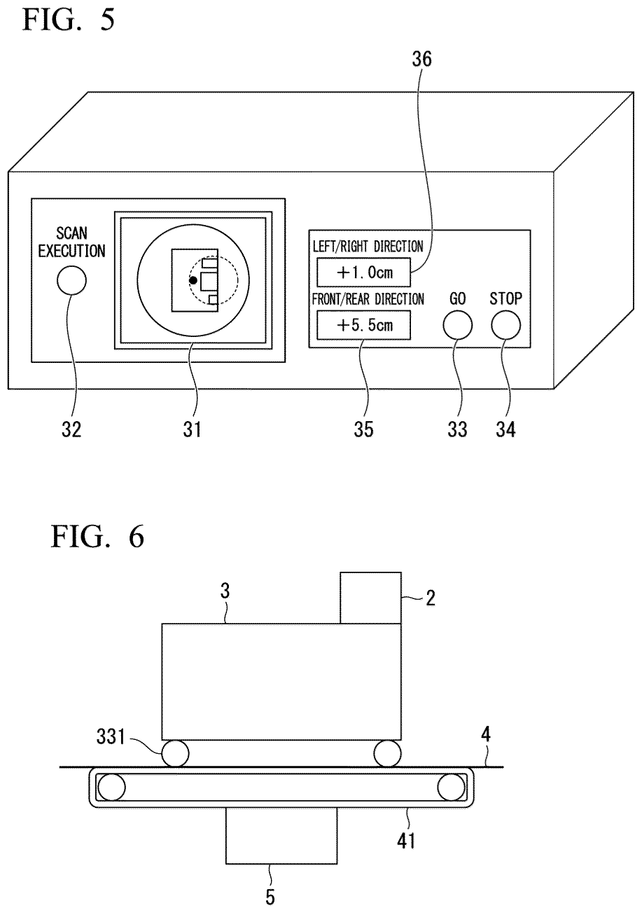

FIG. 5 is a diagram showing the appearance of the position adjustment device.

As shown in FIG. 5, the position adjustment device 1 is provided with a display 31, a scan execution switch 32, an adjustment start switch 33, a movement stop switch, a first movement distance display portion, and a second movement distance display portion. The display 31 displays the scanned image of the scanner 6 including the target device 2. The scan execution switch 32 is a switch for instructing the scanner 6 to start operating. The adjustment start switch 33 is a switch for operating the moving mechanism 5 of the base 3 to control the position of the base 3 including the target device 2. The movement stop switch 34 is a switch that stops the operation of the moving mechanism 5. The first movement distance display portion 35 indicates the distance in the forward/rearward direction calculated by the position adjustment device 1. As an example, the forward/rearward direction is displayed as a + or − distance, where + indicates the distance moved in the forward direction toward the antenna 7 and − indicates the distance moved in the rearward direction away from the antenna 7. The second movement distance display portion 36 is the distance in the left/right direction calculated by the position adjustment device 1. As an example, the left/right distance is displayed as a + or − distance, where + indicates the distance moved to the right toward the antenna 7 and − indicates the distance moved to the left toward the antenna 7.

FIG. 6 is a diagram showing the relationship between the target device, the base, and the turntable.

As shown in FIG. 6, the base 3 on which the target devices 2 are placed may be equipped with wheels 331. As shown in FIG. 4, the turntable 4 may be provided with a guide rail 41. The moving mechanism 5 may be a mechanism that moves the base 3 along the guide rail 41 based on the control from the position adjustment device 1. Alternatively, the position adjustment device 1 may control the movement of the base 3 by rotating the wheels 331.

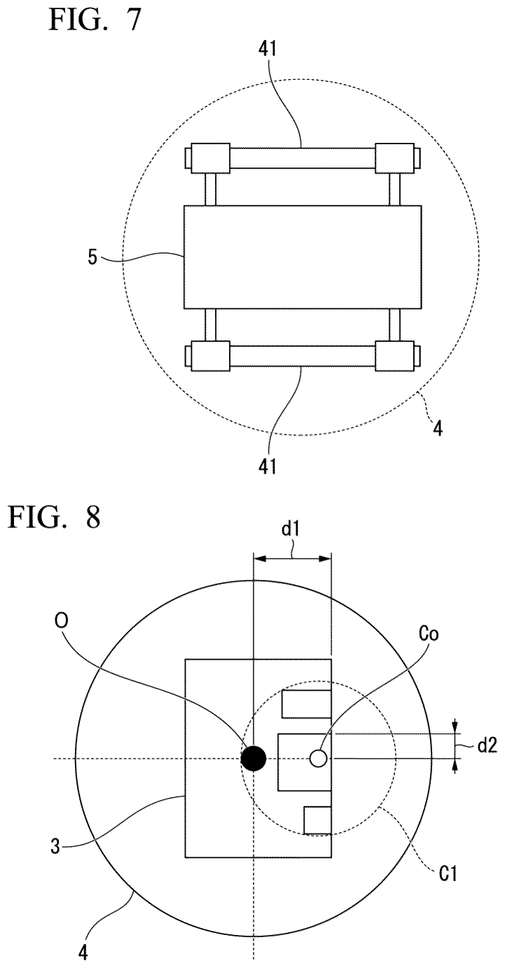

FIG. 7 is a diagram showing the relationship between the moving mechanism and the guide rails.

As shown in FIG. 7, the moving mechanism may be one that moves linearly along a guide rails. For example, in the present disclosure, the moving mechanism 5 may move the base 3 along guide rails so that the target device 2 moves back and forth toward the antenna. In another example, guide rails may be provided in the left/right direction to move the base 3 in the left/right direction.

FIG. 8 is a diagram showing an example of movement information.

The position adjustment device 1, based on the positions of the target devices 2, calculates the virtual outer circumferential circle C1 that is tangent to the inner side of the circle of the target devices 2. The position adjustment device 1 calculates movement information for positioning the center Co of the virtual outer circumferential circle C1 at a position that is determined in advance based on the orientation (or direction of directivity) and position of the antenna 7, such as the center O of the turntable 4. In this disclosure, the movement information is a front/rear movement distance d1 and a left/right movement distance d2. In a case where the predetermined position is the center O of the turntable 4, the position adjustment device 1 moves the base 3 to align the center Co of the virtual outer circumferential circle C1 with the center O of the turntable 4. Alternatively, if the specified position is another position O2, the position adjustment device 1 may calculate movement information to move the virtual outer circumferential circle C1 to position O2, and move the turntable 4 so that the virtual outer circumferential circle C1 aligns with position O2.

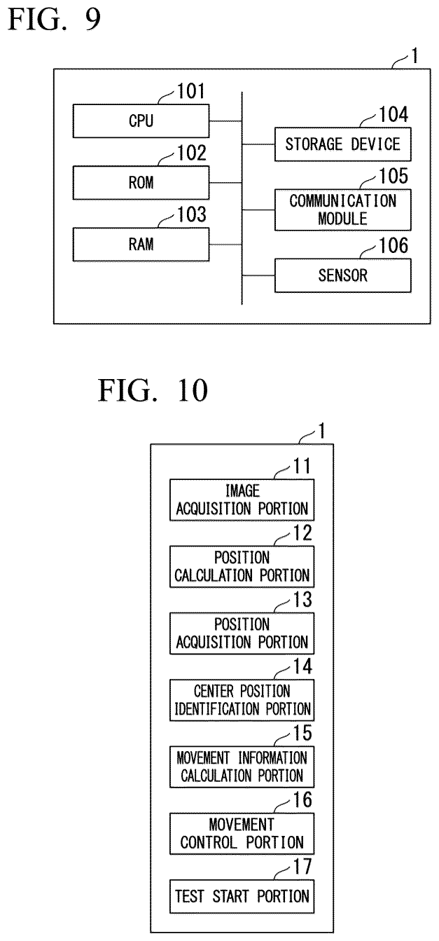

FIG. 9 is a diagram showing the hardware configuration of the position adjustment device.

As shown in FIG. 9, the position adjustment device 1 is a computer equipped with various hardware components such as a Central Processing Unit (CPU) 101, a Read Only Memory (ROM) 102, a Random Access Memory (RAM) 103, a storage device 104, a communication module 105, and a sensor 106.

FIG. 10 is a functional block diagram of the position adjustment device.

As shown in FIG. 10, the position adjustment device 1 performs the functions of an image acquisition portion 11, a position calculation portion 12, a position acquisition portion 13, a center position identification portion 14, a movement information calculation portion 15, a movement control portion 16, and a test start portion 17. The CPU 101 of the position adjustment device 1 may execute a predetermined program to achieve the functions of each processing portion shown in FIG. 10.

The image acquisition portion 11 acquires an image including the target devices 2 from the scanner 6 installed above the target devices 2.

The position calculation portion 12 calculates the positions of the plurality of target devices.

The position acquisition portion 13 acquires the positions of the plurality of target devices.

The center position identification portion 14 identifies the center position of a virtual outer circumferential circle that includes the plurality of target devices 2 inside the circle.

The movement information calculation portion 15 calculates movement information for aligning the center position of the virtual outer circumferential circle to a predetermined position. The movement information indicates, for example, a front/rear movement distance and a left/right movement distance.

The movement control portion 16 controls the movement of the position of the base 3 on which the multiple target devices 2 are placed so that the center position of the virtual outer circumferential circle coincides with the predetermined position based on the movement information.

After detecting the completion of the movement control, the test start portion 17 outputs a start signal for the radiated emission test to an analyzer for the antenna received signal and the target device 2.

In another disclosure, the position adjustment device 1 having functions corresponding to each of the above-mentioned processing units may be configured by connecting a plurality of devices 1 via a communication network. In that case, each device constituting the position adjustment device 1 may execute a predetermined program to achieve the same functions as the position adjustment device 1 of the present disclosure.

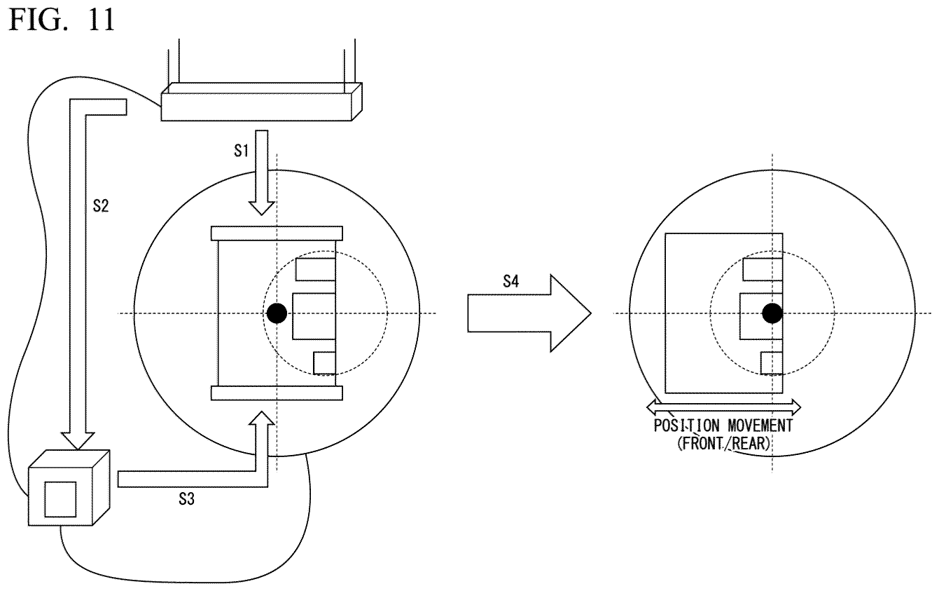

FIG. 11 is a diagram showing an outline of the processing of the radiated emission test system.

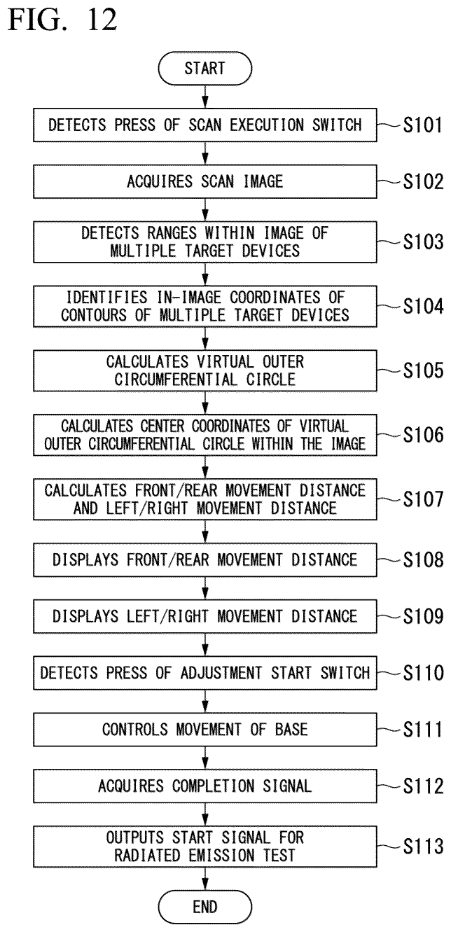

FIG. 12 is a diagram showing the process flow of the position adjustment device.

Next, the details of the processing performed by the position adjustment device 1 will be explained step by step.

A person who measures the radiated emissions of each target device 2 places the target devices 2, including the test target device and auxiliary equipment on the test stand 3. Thereafter, the measurer presses the scan execution switch 32 of the position adjustment device 1. The movement control portion 16 detects that the scan execution switch 32 is pressed (Step S101). The movement control portion 16 outputs a control start signal to the scanner 6. The scanner 6 photographs the area of the base 3 including the target devices 2 based on the control start signal (FIG. 11, S1). The scanner 6 transmits the scanned image of the base 3 to the position adjustment device 1 (FIG. 11, S2).

The image acquisition portion 11 of the position adjustment device 1 acquires the scanned image from the scanner 6 (Step S102). The scanned image may be an image showing a two-dimensional plane including the base 3 in a predetermined three-dimensional space. The image acquisition portion 11 outputs the scanned image to the position calculation portion 12. The position calculation portion 12 detects the ranges within the image of the multiple target devices 2 included in the scanned image by pattern recognition of known target devices 2 (Step S103). The position calculation portion 12 identifies the in-image coordinates of the contours of the multiple target devices 2 detected within the image by pattern recognition (Step S104). The in-image coordinates may be coordinates within the scanned image relative to a predetermined position such as the upper left corner. The position calculation portion 12 outputs the in-image coordinates of the contours of the multiple target devices 2 to the position acquisition portion 13. Note that the function of the position calculation portion 12 may be provided in the scanner 6 or another information processing device, and the position acquisition portion 13 may acquire the in-image coordinates of the contours of the plurality of target devices 2 from the scanner 6 or another information processing device. The position acquisition portion 13 outputs the in-image coordinates of the contours of the multiple target devices 2 to the center position identification portion 14.

Based on the in-image coordinates of the contours of the multiple target devices 2, the center position identifying portion 14 calculates the smallest virtual outer circumferential circle that is tangent to any two or more of those coordinates and includes the target devices 2 inside (Step S105). The center position identifying portion 14 also calculates the center coordinates of the virtual outer circumferential circle within the image (Step S106). The center position identifying portion 14 calculates three-dimensional space coordinates corresponding to the center coordinates within the image of the virtual outer circumferential circle based on a predetermined conversion formula between the coordinate system within the scanned image and the coordinate system in real space. The center position identifying portion 14 outputs to the movement information calculating portion 15 three-dimensional spatial coordinates corresponding to the center coordinates within the image of the virtual outer circumferential circle.

The movement information calculation portion 15 acquires, from a storage portion or the like, three-dimensional coordinates of a predetermined position that is set in advance based on the position, orientation, etc. of the antenna and is stored in advance. The movement information calculation portion 15 calculates the front/rear movement distance d1 and the left/right movement distance d2 for planar movement to align the three-dimensional spatial coordinates corresponding to the central coordinates in the image of the virtual outer circumferential circle with the three-dimensional coordinates of a predetermined position (Step S107). The movement information calculation portion 15 outputs movement information including the front/rear movement distance d1 and the left/right movement distance d2 to the movement control portion 16. The movement information calculation portion 15 displays the front/rear movement distance d1, which is included in the movement information, on the first movement distance display portion 35 (Step S108). The movement information calculation portion 15 displays the left/right movement distance d2, which is included in the movement information, on the second movement distance display portion 36 (Step S109). The measurer presses the adjustment start switch 33 after confirming the front/rear movement distance d1 and the left/right movement distance d2. The measurer pressing the adjustment start switch 33 is an example of an instruction to start position adjustment. The movement information calculation portion 15 detects that the adjustment start switch 33 has been pressed (Step S110). The movement information calculation portion 15 outputs the front/rear movement distance d1, which is the movement information, to the movement control portion 16. The movement information calculation portion 15 may further output the left/right movement distance d2, which is the movement information, to the movement control portion 16.

The movement control portion 16 outputs the acquired front/rear movement distance d1 to the moving mechanism 5 (FIG. 11, S3), and controls the base 3 to move in the front/rear direction (Step S111). The moving mechanism 5 moves the base 3 based on the acquired front/rear movement distance d1 (FIG. 11, S4). As a result, the center of the virtual outer circumferential circle in the image coincides with the position in the front/rear direction of the predetermined position to which the center coordinates should be aligned. The movement control portion 16 detects in a case where the measurer presses the movement stop switch 34. In this case, the movement control portion 16 may be able to output a stop signal to the moving mechanism 5 to stop the movement operation.

If the moving mechanism 5 cannot move in the left/right direction, the measurer then adjusts the left/right direction of the base 3 based on the left/right movement distance d2. As a result, the center of the virtual outer circumferential circle in the image coincides with a predetermined position to which the center coordinates should be aligned. Alternatively, if the left/right direction has already been adjusted, the movement control portion 16 may control the movement of the base 3 in the front/rear direction. The moving mechanism 5 may be a mechanism capable of moving the base 3 in the left/right direction. In this case, the movement control portion 16 outputs the front/rear movement distance d1 to the moving mechanism 5, and then outputs the acquired left/right movement distance d2 to the moving mechanism 5, thereby controlling the base 3 to move in the left/right direction. The moving mechanism 5 moves the base 3 based on the acquired front/rear movement distance d1.

In a case where the moving mechanism 5 completes the movement of the base 3 based on the front/rear movement distance d1 and the left/right movement distance d2, the moving mechanism 5 transmits a control completion signal of the moving mechanism 5 to the position adjustment device 1. The test start portion 17 of the position adjustment device 1 receives the completion signal (Step S112). After detecting the completion signal, the test start portion 17 outputs a start signal for the radiated emission test to the target device 2 and the noise signal measuring device (Step S113). This causes the electronic device in the target device 2 to operate, and the measuring device measures the electromagnetic noise emitted from the electronic device via the antenna 7.

According to the above processing, by simply placing the target devices 2, such as electronic devices or auxiliary devices to be measured, on the base 3, the center of the virtual outer circumferential circle including the target device 2 can be easily aligned to a predetermined position, such as the center of the turntable. As a result, it is possible to obtain test results that meet the requirements of radiated emission test standards and that are highly reproducible.

In the above example, the position adjustment device 1 is communicatively connected to the scanner 6 and the moving mechanism 5 via wires. However, the position adjustment device 1 may be communicatively connected to the scanner 6 and the moving mechanism 5 wirelessly. In this case, the scanner 6, the moving mechanism 5, and the position adjustment device 1 each have a wireless communication unit.

In the above example, the position adjustment device 1 calculates the front/rear movement distance d1 and the left/right movement distance d2 as the movement information. However, the position adjustment device 1 may output the three-dimensional coordinates corresponding to the center position of the virtual outer circumferential circle of the scanned image and the three-dimensional coordinates of a specified position to the moving mechanism 5, and the moving mechanism 5 may calculate a movement path based on the three-dimensional coordinates corresponding to the center position of the virtual outer circumferential circle and the three-dimensional coordinates of the specified position, and control the center position of the virtual outer circumferential circle to move to the specified position. Further, the wheels of the base 3 may be operated based on the control of the moving mechanism 5 to move the center position of the virtual outer circumferential circle to the predetermined position.

In the related technology, the target device 2 is placed on the base 3, a virtual outer circumferential circle and its center are roughly estimated visually, and the test table is manually moved so as to align the center of the virtual outer circumferential circle with a predetermined position such as the center of a turntable. Due to this manual process, precise alignment was difficult to achieve. However, the approach described above can solve such issues.

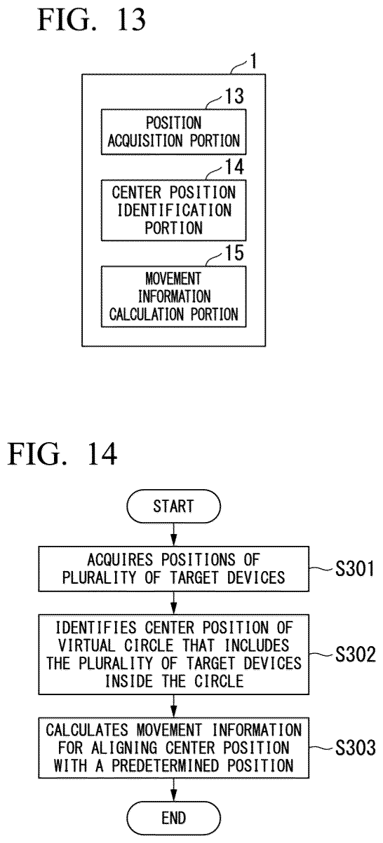

FIG. 13 is a diagram showing another configuration of the position adjustment device.

FIG. 14 is a diagram showing another process flow of the position adjustment device.

The position adjustment device 1 may include at least a position acquisition portion 13, a center position identification portion 14, and a movement information calculation portion 15.

The position acquisition portion 13 acquires the positions of a plurality of target devices (Step S301).

The center position identification portion 14 identifies the center position of a virtual circle that includes the plurality of target devices inside the circle (Step S302).

The movement information calculation portion 15 calculates movement information for aligning the center position with a predetermined position (Step S303).

According to the above example aspects, a center of a circle that includes a plurality of target devices can be easily moved to a predetermined position.

While preferred example embodiments of the disclosure have been described and illustrated above, it should be understood that these are exemplary of the disclosure and are not to be considered as limiting. Additions, omissions, substitutions, and other modifications can be made without departing from the scope of the present disclosure. Accordingly, the disclosure is not to be considered as being limited by the foregoing description, and is only limited by the scope of the appended claims. Moreover, each example embodiment can be appropriately combined with other example embodiments.

Some or all of the above-described example embodiments may be described as, but is not limited to, the following supplementary notes.

### Supplementary Note 1

A position adjustment device comprising:
a position acquisition means for acquiring the positions of a plurality of target devices;
a center position identification means for identifying a center position of a virtual circle that includes the plurality of target devices within the circle; and
a movement information calculation means for calculating movement information for aligning the center position with a predetermined position.

### Supplementary Note 2

The position adjustment device according to Supplementary Note 1, wherein the movement information calculation means calculates the movement information indicating a front/rear movement distance and a left/right movement distance for aligning the center position with the predetermined position.

### Supplementary Note 3

The position adjustment device according to Supplementary Note 1 or 2, comprising a position calculation means for calculating the position of each of the plurality of target devices based on an image of the plurality of target devices, wherein the center position identification means calculates the virtual circle and its center position based on the positions of the respective target devices.

### Supplementary Note 4

The position adjustment device according to any one of supplementary notes 1 to 3,
comprising a movement control means for controlling movement of the position of each of the plurality of target devices based on the movement information so that the center position aligns with the predetermined position.

### Supplementary Note 5

The position adjustment device according to Supplementary Note 4,
wherein the plurality of target devices are placed on a base having a moving mechanism, and
the movement control means controls the moving mechanism to control the movement of the positions of the plurality of target devices arranged on the base.

### Supplementary Note 6

The position adjustment device according to Supplementary Note 5,
wherein the predetermined position is a position that is set in advance according to the position and orientation of an antenna;
each of the plurality of target devices is an electronic device that generates electromagnetic noise; and
the movement control means controls the moving mechanism based on an instruction to start position adjustment.

### Supplementary Note 7

The position adjustment device according to Supplementary Note 6, comprising:
a test start means for outputting a start signal for a radiated emission test regarding electromagnetic noise generated by the electronic device after detecting completion of control of the moving mechanism based on the instruction to start the position adjustment.

### Supplementary Note 8

The position adjustment device according to Supplementary Note 3, comprising:
an image acquisition means for acquiring the image from a scanner installed above the plurality of target devices.

### Supplementary Note 9

A position adjustment method comprising:
acquiring the positions of a plurality of target devices;
identifying a center position of a virtual circle that includes the plurality of target devices within the circle; and
calculating movement information to align the center position to a predetermined position.

### Supplementary Note 10

The position adjustment method according to Supplementary Note 9,
calculating the movement information indicating the front/rear movement distance and the left/right movement distance for aligning the center position with the predetermined position.

### Supplementary Note 11

The position adjustment method according to Supplementary Note 9 or 10,
calculating the positions of the plurality of target devices based on an image of the plurality of target devices; and
calculating the virtual circle and its center position based on the positions of the respective target devices.

### Supplementary Note 12

The position adjustment method according to any one of supplementary notes 9 to 11,
controlling movement of the position of each of the plurality of target devices based on the movement information so that the center position aligns with the predetermined position.

### Supplementary Note 13

The position adjustment method according to Supplementary Note 12,
wherein the plurality of target devices are placed on a base having a moving mechanism, and
the moving mechanism is controlled to control the movement of the positions of the plurality of target devices arranged on the base.

### Supplementary Note 14

The position adjustment method according to Supplementary Note 13,
wherein the predetermined position is a position that is set in advance according to the position and orientation of an antenna;
each of the plurality of target devices is an electronic device that generates electromagnetic noise; and
the moving mechanism is controlled based on an instruction to start position adjustment.

### Supplementary Note 15

The position adjustment method according to Supplementary Note 14,
outputting a start signal for a radiated emission test regarding electromagnetic noise generated by the electronic device after detecting completion of control of the moving mechanism based on the instruction to start the position adjustment.

### Supplementary Note 16

The position adjustment method according to Supplementary Note 11,
acquiring the image from a scanner installed above the plurality of target devices.

### Supplementary Note 17

A program that causes a computer to function as
a position acquisition means for acquiring the positions of a plurality of target devices;
a center position identification means for identifying a center position of a virtual circle that includes the plurality of target devices within the circle; and
a movement information calculation means for calculating movement information for aligning the center position with a predetermined position.

### Supplementary Note 18

The program according to Supplementary Note 17,
wherein the movement information calculation means calculates the movement information indicating a front/rear movement distance and a left/right movement distance for aligning the center position with the predetermined position.

### Supplementary Note 19

The program according to Supplementary Note 17 or 18,
causing a computer to function as a position calculation means for calculating the position of each of the plurality of target devices based on an image of the plurality of target devices,
wherein the center position identification means calculates the virtual circle and its center position based on the positions of the respective target devices.

### Supplementary Note 20

The program according to any one of supplementary notes 17 to 19,
causing a computer to function as a movement control means for controlling movement of the position of each of the plurality of target devices based on the movement information so that the center position aligns with the predetermined position.

### Supplementary Note 21

The program according to Supplementary Note 20,
wherein the plurality of target devices are placed on a base having a moving mechanism, and
the movement control means controls the moving mechanism to control the movement of the positions of the plurality of target devices arranged on the base.

### Supplementary Note 22

The program according to Supplementary Note 21,
wherein the predetermined position is a position that is set in advance according to the position and orientation of an antenna;
each of the plurality of target devices is an electronic device that generates electromagnetic noise; and
the movement control means controls the moving mechanism based on an instruction to start position adjustment.

### Supplementary Note 23

The program according to Supplementary Note 22,
causing a computer to function as a test start means for outputting a start signal for a radiated emission test regarding electromagnetic noise generated by the electronic device after detecting completion of control of the moving mechanism based on the instruction to start the position adjustment.

### Supplementary Note 24

The program according to Supplementary Note 19,
causing a computer to function as an image acquisition means for acquiring the image from a scanner installed above the plurality of target devices.

What is claimed is:

1. A position adjustment device comprising:
at least one memory configured to store instructions; and
at least one processor configured to execute the instructions to:
acquire positions of a plurality of target devices;
identify a center position of a virtual circle so that the plurality of target devices are located within the virtual circle; and
calculate movement information for aligning the center position with a predetermined position.

2. The position adjustment device according to claim 1, wherein the at least one processor is configured to execute the instructions to calculate the movement information indicating a front/rear movement distance and a left/right movement distance for aligning the center position with the predetermined position.

3. The position adjustment device according to claim 2, wherein the at least one processor is configured to execute the instructions to:
calculate a position of each of the plurality of target devices based on an image of the plurality of target devices; and
calculate the virtual circle and the center position of the virtual circle based on the positions of the respective target devices.

4. The position adjustment device according to claim 3, wherein the at least one processor is configured to execute the instructions to control movement of the position of each of the plurality of target devices based on the movement information so that the center position aligns with the predetermined position.

5. The position adjustment device according to claim 4, wherein the plurality of target devices are placed on a base having a moving mechanism, and
wherein the at least one processor is configured to execute the instructions to control the moving mechanism to control the movement of the positions of the plurality of target devices arranged on the base.

6. The position adjustment device according to claim 5, wherein the predetermined position is a position that is set in advance according to a position and an orientation of an antenna,
wherein each of the plurality of target devices is an electronic device that generates electromagnetic noise, and
wherein the at least one processor is configured to execute the instructions to control the moving mechanism based on an instruction to start position adjustment.

7. The position adjustment device according to claim 6, wherein the at least one processor is configured to execute the instructions to output a start signal for a radiated emission test regarding electromagnetic noise generated by the electronic device after detecting completion of control of the moving mechanism based on the instruction to start the position adjustment.

8. The position adjustment device according to claim 7, wherein the at least one processor is configured to execute the instructions to acquire the image from a scanner installed above the plurality of target devices.

9. A position adjustment method comprising:
acquiring positions of a plurality of target devices;
identifying a center position of a virtual circle so that the plurality of target devices are located within the virtual circle; and
calculating movement information for aligning the center position with a predetermined position.

10. The position adjustment method according to claim 9, further comprising calculating the movement information indicating a front/rear movement distance and a left/right movement distance for aligning the center position with the predetermined position.

11. The position adjustment method according to claim 10, further comprising:
calculating a position of each of the plurality of target devices based on an image of the plurality of target devices; and
calculating the virtual circle and the center position of the virtual circle based on the positions of the respective target devices.

12. The position adjustment method according to claim 11, further comprising controlling movement of the position of each of the plurality of target devices based on the movement information so that the center position aligns with the predetermined position.

13. The position adjustment method according to claim 12, wherein the plurality of target devices are placed on a base having a moving mechanism, and
wherein the method further comprises controlling the moving mechanism to control the movement of the positions of the plurality of target devices arranged on the base.

14. The position adjustment method according to claim 13, wherein the predetermined position is a position that is set in advance according to a position and an orientation of an antenna,
wherein each of the plurality of target devices is an electronic device that generates electromagnetic noise, and
wherein the method further comprises controlling the moving mechanism based on an instruction to start position adjustment.

15. The position adjustment method according to claim 14, further comprising outputting a start signal for a radiated emission test regarding electromagnetic noise generated by the electronic device after detecting completion of control of the moving mechanism based on the instruction to start the position adjustment.

16. The position adjustment method according to claim 15, further comprising acquiring the image from a scanner installed above the plurality of target devices.

17. A non-transitory storage medium storing a program that causes a computer to execute:
acquiring positions of a plurality of target devices;
identifying a center position of a virtual circle so that the plurality of target devices are located within the virtual circle; and
calculating movement information for aligning the center position with a predetermined position.
